(19) United States
(12) Patent Application Publication
(10) Pub. No.: US 2014/0110585 A1
(43) Pub. Date: Apr. 24, 2014

(54) Multi-Spectral Sensor System Comprising a Plurality of Buttable Focal Plane Arrays

(71) Applicant: James Justice, Newport Beach, CA (US)

(72) Inventor: James Justice, Newport Beach, CA (US)

(21) Appl. No.: 13/655,563

(22) Filed: Oct. 19, 2012

(51) Int. Cl. H01L 27/146

(52) U.S. Cl. 250/349; 250/208.1

(57) ABSTRACT

A multi-spectral sensor assembly having a plurality of mosaics of four-side buttable focal plane arrays in which each mosaic array is responsive to a different range of the electromagnetic spectrum. The scene image is received through a baffled solar shade to a beam-splitting element which transmits a first portion of the received image in a first electromagnetic spectrum to a short wave infrared (SWIR) buttable focal plane array detector element. The beam-splitting element transmits a second portion of the received image in a second electromagnetic spectrum to a mid-wave infrared (MWIR) buttable focal plane array detector element by means of a folding mirror. The first and second portions of the received image are passed through a filter wheel having multiple selectable optical filters to provide a multi-spectral imaging system.

### CROSS-REFERENCE TO RELATED APPLICATIONS

This application is a continuation-in-part of U.S. patent application Ser. No. 12/563,794, entitled “Active Tracking and Imaging Sensor System Comprising Illuminator Analysis Function”, now pending, filed on Aug. 1, 2012, which claims the benefit of U.S. Provisional Pat. Application No. 61/513,910, entitled “Miniature Active Tracking and Imaging Sensor System” filed on Aug. 1, 2011, and is a continuation-in-part application of U.S. patent application Ser. No. 13/397,275, entitled “Long Range Acquisition and Tracking SWIR Sensor System Comprising Micro-Lamellar Spectrometer” filed on Feb. 15, 2012, now pending, and is a continuation-in-part application of U.S. patent application Ser. No. 13/010,745 entitled “Large Displacement Micro-lamellar Grating Interferometer”, now pending, filed on Jan. 20, 2011, which in turn claims priority to U.S. Provisional Pat. Application No. 61/336,271, entitled “Micro Lamellar Grating Interferometer”, filed on Jan. 22, 2010, and which is a continuation-in-part application of U.S. patent application Ser. No. 13/108,172 entitled “Sensor Element and System Comprising Wide Field of View 3-D Imaging LIDAR”, now pending, filed on May 16, 2011, which in turn claims priority to U.S. Provisional Pat. Application No. 61/395,712, entitled “Autonomous Landing at Unprepared Sites for a Cargo Unmanned Air System” filed on May 18, 2010, pursuant to 35 USC 119, which applications are fully incorporated herein by reference.

This application claims the benefit of U.S. Provisional Pat. Application No. 61/551,801, entitled “Multi-Spectral Mosaic Sensors” filed on Oct. 26, 2011, pursuant to 35 USC 119, which application is incorporated fully herein by reference.

### STATEMENT REGARDING FEDERALLY SPONSORED RESEARCH AND DEVELOPMENT

N/A

### BACKGROUND OF THE INVENTION

1. Field of the Invention

The invention relates generally to the field of electronic imaging systems and methods. More specifically, the invention relates to an advanced multi-spectral sensor assembly which, in one embodiment, comprises a plurality of mosaics of four-side buttable focal plane arrays wherein each mosaic array is responsive to a different range of the electromagnetic spectrum such as the SWIR spectrum and the MWIR spectrum.

2. Description of the Related Art

Space environments are extremely challenging with respect to imaging sensor suites due to the size, weight and power or “SWaP” restrictions inherent in satellite operations coupled with extreme lighting and temperature environments which may include very dark environments or full solar exposure, all in the context of the large distances the target may be from the imaging suite. Nonetheless, space-based imaging of land and marine scenes of interests has unique reconnaissance benefits unachievable from land- or aerial-based imaging suites making satellite-based imaging sensor suites particularly valuable in certain civilian and military applications.

What is needed to overcome the aforementioned challenges is a compact, low-power, lightweight imaging sensor suite that can image, identify and assess Earth features in multiple electromagnetic spectra from space-based assets.

### BRIEF SUMMARY OF THE INVENTION

The invention is a multi-spectral sensor assembly which, in one embodiment, comprises a plurality of mosaics of four-side buttable focal plane arrays wherein each mosaic array is responsive to a different range of the electromagnetic spectrum such as the SWIR spectrum and the MWIR spectrum.

The scene image is received through a baffled solar shade as an optical input to a beam-splitting element which splits a first portion of the received image into a first spectrum to a short wave infrared (SWIR) buttable focal plane array detector element.

The beam-splitter splits a second portion of the received image to a mid-wave infrared (MWIR) buttable focal plane array detector element by means of a folding minor. Each of the first and second portions of the optical input may be passed through a filter wheel having multiple selectable filters for filtering preselected subsets of the electromagnetic spectrum of the first and second spectrums to the respective detectors.

In a first aspect of the invention, a multi-spectral imaging sensor system is provided comprising a first focal plane array that is responsive to a predetermined first range of the electromagnetic spectrum. A second focal plane array is provided that is responsive to a predetermined second range of the electromagnetic spectrum along with a beam-splitter configured to split an optical input into the first range and the second range. The beam-splitter is configured for transmitting the first range to the first focal plane array. A folding mirror is configured for transmitting the second range to the second focal plane array. At least one optical filter set is provided in the system comprising a plurality of selectable optical filters that is configured to permit the selective transmission of one of a plurality of predetermined spectrum subsets of the first or second ranges to the respective first or second focal plane arrays.

In a second aspect of the invention, the first range comprises the short wave infrared spectrum of about 1.4 to about 3.2 microns and the second range comprises the medium wave infrared spectrum of about 3.0 to about 8.0 microns.

In a third aspect of the invention, the plurality of predetermined spectrum subsets comprises each of the 2.0-2.5, the 2.69-2.95 and the 3.0-3.2 micron range of wavelengths.

In a fourth aspect of the invention, the plurality of predetermined subsets comprises each of the 3.5-4.0, the 4.2-4.45, and the 4.45-5.0 micron range of wavelengths.

In a fifth aspect of the invention, at least one of the first and second focal plane arrays is comprised of a multi-side buttable mosaic focal plane array assembly such as a three- or four-side buttable focal plane array mosaic.

In a sixth aspect of the invention, the system further comprises a solar shade element for receiving the optical input from a scene of interest.

While the claimed apparatus and method herein has or will be described for the sake of grammatical fluidity with functional explanations, it is to be understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112, are to be accorded full statutory equivalents under 35 USC 112.

### DESCRIPTION OF THE SEVERAL VIEWS OF THE DRAWINGS

FIG. 1 depicts a cross-section of a preferred embodiment of the sensor system of the invention.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE INVENTION

A multi-spectral sensor system is disclosed which, in a preferred embodiment of the system of the invention, may comprise a plurality of four-side buttable mosaics of stacked focal plane array elements which mosaics are separately responsive to different ranges (or bands) of the electromagnetic spectrum such as the SWIR band and MWIR band of the electromagnetic spectrum.

An example of a buttable focal plane array mosaic suitable for use in the instant invention is disclosed in U.S. Pat. No. 7,335,576 entitled “Method for Precision Die Integrated Circuit Die Singulation Using Differential Etch Rates”.

Beam-splitting optics and a folding mirror optical assembly may be incorporated into the system to divide or split the received optical input in the form of an electromagnetic beam into a predetermined plurality of split output beams of different ranges of the electromagnetic spectrum.

The plurality of split beams that comprise the optical input to the system define a first spectrum having a first electromagnetic range of wavelengths and a second spectrum having a second electromagnetic range of wavelengths.

The spectral content of each of the split beams from the optical input is within a separate, predetermined range of the electromagnetic spectrum but may include some overlap of wavelengths. The plurality of split beams are transmitted to, and imaged upon, a plurality of focal plane arrays (“FPA”) or a plurality of mosaics comprised of buttable FPA tiles; each FPA or mosaic assembly dedicated to and having a responsivity to the separate, predetermined electromagnetic range of the respective split beams.

One or more selectable optical filters may be provided to filter the respective split beams that are imaged onto the respective FPAs or mosaic assemblies.

The FPAs or mosaic assemblies may be in the form of HgCdTe, 12 micron pitch, 9000×9000 pixel arrays that, in a tiled or mosaic format, enable very large FPA imaging surface areas.

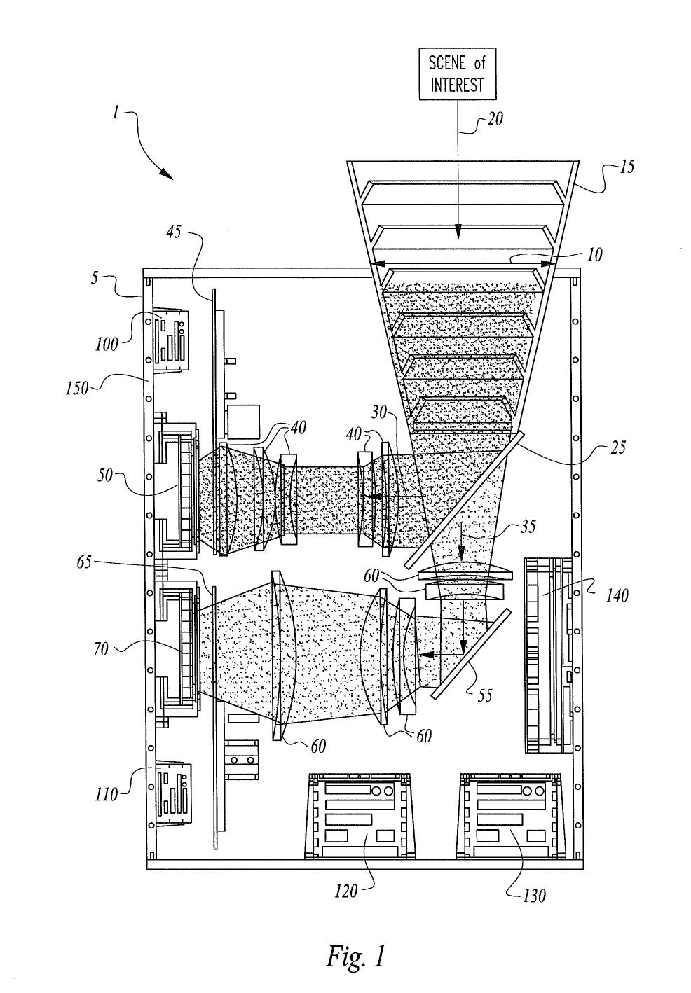

Turning now to FIG. 1, the major elements of a preferred embodiment of the system of the invention are depicted.

Multi-spectral sensor system 1 is comprised of housing 5, aperture 10, and solar or sun shade 15 configured for receiving optical input 20. System 1 further comprises beam-splitting element 25 for splitting optical input 20 into a first spectrum 30 and a second spectrum 35. First spectrum 30 may comprise the electromagnetic short wave infrared (SWIR) range and second spectrum 35 may comprise the medium wave infrared (MWIR) range. Telescope receiver input aperture optics (not shown) in a preferred embodiment of the invention are a 15 diameter cm set of optics.

System 1 further comprises a set of first optics 40, in the illustrated embodiment, dedicated to the SWIR range in cooperation with a first optical filter 45 and a first focal plane array 50 which, in the illustrated embodiment depicts a four-side buttable mosaic of stacked focal plane array assemblies responsive to the SWIR spectrum.

System 1 further comprises a set of second optics 60, in the illustrated embodiment, dedicated to the MWIR range in cooperation with a second optical filter 65 and a second focal plane array 70 which, in the illustrated embodiment depicts a four-side buttable mosaic of stacked focal plane array assemblies responsive to the MWIR spectrum.

It is expressly noted that the above first and second focal plane array responsivities are not limited to the SWIR and MWIR spectrums and each may be provided having any range of electromagnetic responsivity selected by the user.

A preferred embodiment of system 1 further comprises first spectrum control electronics 100, second spectrum control electronics 110, second spectrum mission data processor 120, first spectrum mission data processor 130 and system interface and camera system control electronics 140 disposed within housing 5. Housing 5 is further comprised of a radiativly-cooled lateral member or side 150 for heat transfer and cooling of the electronics, FPAs and optical filters mounted thereon.

Lateral member 150 may desirably be in thermal communication with an external radiative or other cooling element for the dissipation of waste heat from system 1 to the environment such as is provided in space satellite systems.

In operation, electromagnetic radiation in the form of an optical input 20 from a scene of interest is received through sun or solar shade 15 of aperture 10. Solar shade 15 is preferably provided with a non-optically reflective interior surface and comprising a set of optical baffle elements and configured to eliminate solar glare from being received by or reflected into the optics of system 1.

In the preferred embodiment of FIG. 1, beam-splitter 25 optically splits and “diverts” a portion of the received scene image in the form of an optical input 20 into two predetermined ranges of the electromagnetic spectrum. First and second spectrums 30 and 35 are received by each of the first and second focal plane arrays 50 and 70 using beam-splitting means such as by using a beam-splitting prism, dichroic or partially-mirrored beam-splitting element or equivalent beam-splitting means as are well-known in the optical arts.

Suitable first and second optics 40 and 60 respectively, are provided and configured for the range of selected wavelengths matching those of the first and second FPAs 50 and 70 employed in the system.

First spectrum 30 is split off from optical input 20, passed through first optics 40 and incident upon first FPA 50. First FPA 50 may comprise any suitable FPA responsive to any preselected wavelength and may comprise a mosaic of four-side buttable stacked focal plane array assemblies to enable very large system detector elements.

Preferably, one or a set of user-selectable first optical filter elements 45 are provided, such as in the form of a rotatable optical filter wheel. In an exemplar embodiment, the filter elements for a SWIR FPA may comprise filters for individual spectral bands in the each of the ranges of 2.0-2.5, 2.69-2.95 and 3.0-3.2 micron wavelengths.

Second spectrum 35 is passed through beam-splitter 25 and transmitted to second optics 60 by means of folding mirror 55.

Second spectrum 35 is passed to, and incident upon, second FPA 70. Second FPA 70 may comprise any suitable FPA responsive to any preselected wavelength and may comprise a mosaic of four-side buttable stacked focal plane array assemblies to enable very large system detector elements.

Preferably, one or a set of second user-selectable optical filter elements 65 are provided, such as in the form of a rotatable optical filter wheel. In an exemplar embodiment, the filter elements for a MWER FPA may comprise filters for individual spectral bands in each of the ranges of 3.5-4.0, 4.2-4.45, and 4.45-5.0 micron wavelengths.

The disposition of the first and second FPAs, first and second optical filters and first and second control electronics on lateral internal surface 150 is desirable to maintain cooling of the various elements in operation such as by means of thermal communication with a radiative cooling element.

In this manner, a single telescope, multi-spectral sensor system is provided for full-Earth observation with reduced volume and weight for deployment on small SatClass satellites.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed in above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements. The claims are thus to be understood to include what is specifically illustrated and described above, what is conceptually equivalent, what can be obviously substituted and also what essentially incorporates the essential idea of the invention.

I claim:

1. A multi-spectral imaging sensor system comprising:
a first focal plane array responsive to a predetermined first range of the electromagnetic spectrum,
a second focal plane array responsive to a predetermined second range of the electromagnetic spectrum,
a beam-splitter configured to split an optical input into the first range and the second range and for transmitting the first range to the first focal plane array,
a folding mirror configured for transmitting the second range to the second focal plane array, and,
an optical filter set comprising a plurality of selectable optical filters configured to permit the selective transmission of one of a plurality of predetermined spectrum subsets of the first or second range to the respective first or second focal plane array.

2. The system of claim 1 wherein the first range comprises the short wave infrared spectrum of about 1.4 to about 3.2 microns and the second range comprises the medium wave infrared spectrum of about 3.0 to about 8.0 microns.

3. The system of claim 2 wherein the plurality of predetermined spectrum subsets comprises each of the 2.0-2.5, the 2.69-2.95 and the 3.0-3.2 micron range of wavelengths.

4. The system of claim 2 wherein the plurality of predetermined subsets comprise each of the 3.5-4.0, the 4.2-4.45, and the 4.45-5.0 micron range of wavelengths.

5. The system of claim 1 wherein at least one of the first and second focal plane arrays is comprised of a four-side buttable mosaic focal plane array assembly.

6. The system of claim 1 further comprising a solar shade element for receiving the optical input from a scene of interest.
